(19) United States
(12) Patent Application Publication
(10) Pub. No.: US 2018/0210261 A1
(43) Pub. Date: Jul. 26, 2018

(54) LIQUID CRYSTAL PANEL DRIVE CIRCUIT AND LIQUID CRYSTAL DISPLAY DEVICE

(71) Applicants: Yu-yeh CHEN, Shenzhen, Guangdong (CN); Nianmao WANG, Shenzhen, Guangdong (CN)

(72) Inventors: Yu-yeh CHEN, Shenzhen, Guangdong (CN); Nianmao WANG, Shenzhen, Guangdong (CN)

(73) Assignee: Shenzhen China Star Optoelectronics Technology Co., Ltd., Shenzhen, Guangdong (CN)

(21) Appl. No.: 15/327,232

(22) PCT Filed: Dec. 5, 2016
(86) PCT No.: PCT/CN2016/108544

§ 371 Date: Jan. 18, 2017

(30) Foreign Application Priority Data
Oct. 26, 2016 (CN) 201610944290.4

(51) Int. Cl. G02F 1/1345; H01L 23/00; H05K 1/14; H05K 1/18; G09G 3/36

(52) U.S. Cl. CPC G02F 1/13452; H01L 24/50; H05K 1/147; H05K 1/189; G09G 2320/0276; G09G 3/3688; H05K 2201/049; H05K 2201/10136; H01L 2924/1426; G09G 3/3696

(57) ABSTRACT

Provided are a liquid crystal panel drive circuit and a liquid crystal display device. The liquid crystal panel drive circuit comprises a first signal transmission board, a second signal transmission board, a Gamma voltage generation module and N data drive chip, and the first signal transmission board and the second signal transmission board are located at the same side of the liquid crystal panel and are separately located with the liquid crystal panel respectively, and the Gamma voltage generation module is located on the first signal transmission board employed to generate an original Gamma voltage signal, and the first data drive chip to the (N-M)th data drive chip are separately located between the first signal transmission board and the liquid crystal panel, and the (N-M+1)th data drive chip to the Nth data drive chip are separately located between the second signal transmission board and the liquid crystal panel.

### CROSS REFERENCE

This application claims the priority of Chinese Patent Application No. 201610944290.4, entitled “Liquid crystal panel drive circuit and liquid crystal display device”, filed on Oct. 26, 2016, the disclosure of which is incorporated herein by reference in its entirety.

### FIELD OF THE INVENTION

The present invention relates to a flat panel display field, and more particularly to a liquid crystal panel drive circuit and a liquid crystal display device.

### BACKGROUND OF THE INVENTION

The Liquid Crystal Display (LCD) is a common electronic device, and possesses properties of low power consumption, small volume and light weight. Therefore, it has been favored by the users. In the development process of the liquid crystal display device, promoting the image quality of the liquid crystal display device is always the target which the developer is chasing for. However, for the liquid crystal display device of the same image quality, the material cost is also the key of promoting the competitiveness of the liquid crystal display device. The liquid crystal display device comprises a liquid crystal panel drive circuit. The liquid crystal panel drive circuit generally comprises a Gamma voltage generation module, a first signal transmission board, a second signal transmission board and a plurality of data drive chips. In the normal condition, both the first signal transmission board and the second signal transmission board are Printed Circuit Boards (PCB). The Gamma voltage generation module is located on one solo PCB which is not the first signal transmission board or the second signal transmission board. The PCB of locating the Gamma voltage generation module is respectively coupled to the first signal transmission board and the second signal transmission board through a flexible circuit to transmit the original Gamma voltage signal generated by the Gamma voltage generation module to the corresponding drive chips through the first signal transmission board and the second signal transmission board. Accordingly, the amount of the PCBs used in the liquid crystal panel drive circuit in prior art is more, and then the material cost of the liquid crystal display device is increased.

### SUMMARY OF THE INVENTION

The present invention provides a liquid crystal panel drive circuit, employed for driving a liquid crystal panel, wherein the liquid crystal panel drive circuit comprises a first signal transmission board, a second signal transmission board, a Gamma voltage generation module and N data drive chips, and the first signal transmission board and the second signal transmission board are located at the same side of the liquid crystal panel and are separately located with the liquid crystal panel respectively, and the Gamma voltage generation module is located on the first signal transmission board, and the Gamma voltage generation module is employed to generate an original Gamma voltage signal, and the first data drive chip to the (N-M)th data drive chip are separately located between the first signal transmission board and the liquid crystal panel, and the (N-M+1)th data drive chip to the Nth data drive chip are separately located between the second signal transmission board and the liquid crystal panel, and the first data drive chip to the Nth data drive chip are respectively employed to obtain a K scale Gamma voltage drive signal according to the original Gamma voltage signal, and the K scale Gamma voltage drive signal is employed to drive the liquid crystal panel to achieve displays with various brightnesses, wherein N, M and K are all positive integers, and M is smaller than N, and the data drive chip at the first signal transmission board which is farthest away from the second signal transmission board to the data drive chip at the second signal transmission board which is farthest away from the first signal transmission board are sequentially named to be the first data drive chip to the Nth data drive chip.

The original Gamma voltage signal is transmitted to the first data drive chip to the (N-M)th data drive chip through the first signal transmission board, and the original Gamma voltage signal is transmitted to the second signal transmission board through the first signal transmission board and wires located in a non display region of an array substrate of the liquid crystal panel, and the original Gamma voltage signal is transmitted to the (N-M+1)th data drive chip to the Nth data drive chip through the second signal transmission board.

The liquid crystal panel drive circuit further comprises N flexible films which are separately located, and the N flexible films are correspondingly located to the data drive chips one by one, and the N flexible films are employed to carry the data drive chips correspondingly located to the flexible films, and the first flexible film to the (N-M)th flexible film are respectively employed to electrically couple the first signal transmission board with the first data drive chip to the (N-M)th data drive chip; the (N-M+1)th flexible film to the Nth flexible film are respectively employed to electrically couple the second signal transmission board with the (N-M+1)th data drive chip to the Nth data drive chip, wherein the flexible film at the first signal transmission board which is farthest away from the second signal transmission board to the flexible film at the second signal transmission board which is farthest away from the first signal transmission board are sequentially named to be the first flexible film to the Nth flexible film.

The first signal transmission board and the second signal transmission board are not coplanar with the array substrate of the liquid crystal panel.

The original Gamma voltage signal is transmitted to the first data drive chip through the first signal transmission board, and the original Gamma voltage signal is transmitted to the second data drive chip and the Nth data drive chip through wires located in a non display region of an array substrate of the liquid crystal panel.

The liquid crystal panel drive circuit further comprises N flexible films which are separately located, and the N flexible films are correspondingly located to the N data drive chips one by one, and the flexible films are employed to carry the data drive chips correspondingly located to the flexible films, and the flexible film carrying the first data drive chip is also employed to electrically couple the first signal transmission board with the first data drive chip to transmit the original Gamma voltage signal to the first data drive chip through the first signal transmission board.

The first data drive chip comprises a first amplifier, and the first amplifier is employed to compensate and enhance the original Gamma voltage signal received by the first data drive chip in a transmission process.

The (N-M+1)th data drive chip comprises a second amplifier, and the second amplifier is employed to compensate and enhance the original Gamma voltage signal received by the (N-M+1)th data drive chip in a transmission process.

The (N-M+1)th data drive chip comprises a second amplifier, and the second amplifier is employed to compensate and enhance the original Gamma voltage signal received by the (N-M+1)th data drive chip in a transmission process.

In comparison with prior art, in the liquid crystal panel drive circuit of the present invention, the Gamma voltage generation circuit is located on the first signal transmission board to eliminate the required board of locating the Gamma voltage generation module, and to reduce the flexible circuit board previously located from the Gamma voltage generation module to the first signal transmission board and the second transmission board. Therefore, the material cost of the liquid crystal panel drive circuit of the present invention is lower.

The present invention further provides a liquid crystal display device. The liquid crystal display device comprises the aforesaid liquid crystal display panel drive circuit described in any of the aforesaid embodiments.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structure diagram of a liquid crystal panel drive circuit according to the first preferred embodiment of the present invention.

FIG. 2 is a structure diagram of a liquid crystal panel drive circuit according to the second preferred embodiment of the present invention.

FIG. 3 is an enlarged structure diagram of I position and II position in FIG. 2.

FIG. 4 is a structure diagram of a liquid crystal display device according to one preferred embodiment of the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

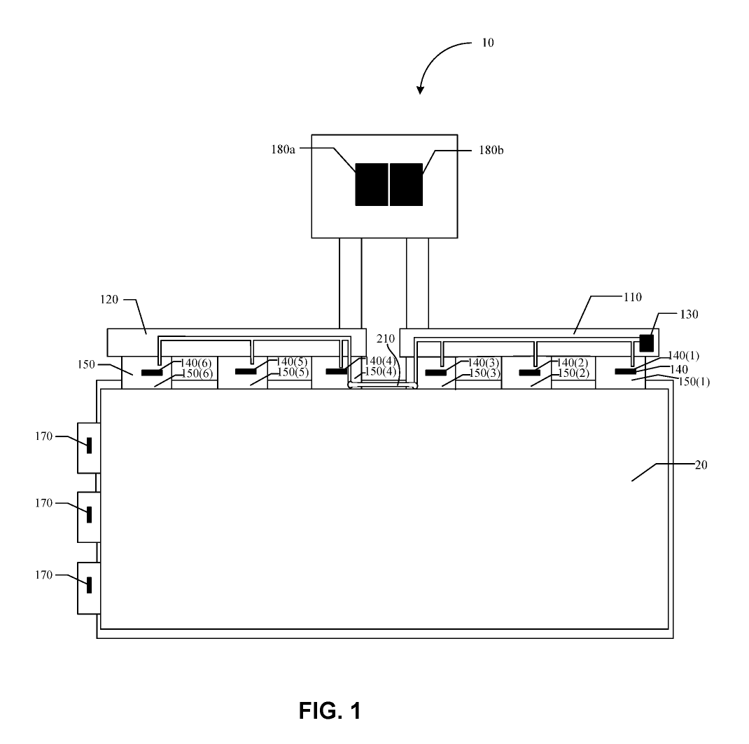

Please refer to FIG. 1. FIG. 1 is a structure diagram of a liquid crystal panel drive circuit according to the first preferred embodiment of the present invention. The liquid crystal panel drive circuit 10 is employed for driving a liquid crystal panel 20. The liquid crystal panel drive circuit 10 comprises a first signal transmission board (X Board) 110, a second signal transmission board (X Board) 120, a Gamma voltage generation module 130 and N data drive chips (Source Driver) 140. The first signal transmission board 110 and the second signal transmission board 120 are located at the same side of the liquid crystal panel 20 and are separately located with the liquid crystal panel 20, respectively. The Gamma voltage generation module 130 is located on the first signal transmission board 110, and the Gamma voltage generation module 130 is employed to generate an original Gamma voltage signal. The first data drive chip 140(1) to the (N-M)th data drive chip 140(N-M) are separately located between the first signal transmission board 110 and the liquid crystal panel 20, and the (N-M+1)th data drive chip 140(N-M+1) to the Nth data drive chip 140(N) are separately located between the second signal transmission board 120 and the liquid crystal panel 20. The first data drive chip 140(1) to the Nth data drive chip 140(N) are respectively employed to obtain a K scale Gamma voltage drive signal according to the original Gamma voltage signal, and the K scale Gamma voltage drive signal is employed to drive the liquid crystal panel 20 to achieve displays with various brightnesses. N, M and K are all positive integers, and M is smaller than N. The data drive chip 140 at the first signal transmission board 110 which is farthest away from the second signal transmission board 120 to the data drive chip 140 at the second signal transmission board 120 which is farthest away from the first signal transmission board 110 are sequentially named to be the first data drive chip 140(1) to the Nth data drive chip 140(N).

In one embodiment, the first signal transmission board 110 and the second signal transmission board 120 are Printed Circuit Boards (PCB).

The specific process that the first data drive chip to the Nth data drive chip are respectively employed to obtain a K scale Gamma voltage drive signal according to the original Gamma voltage signal is introduced below. It is illustrated that the original Gamma voltage signal is through one data drive chip. The data chip comprises a series resistance circuit (R-string). After the original Gamma voltage signal is through the series resistance circuit, the K scale Gamma voltage drive signal, such as a 256 gray scales Gamma voltage drive signal can be obtained.

For convenience, the first data drive chip is labeled with 140(1), the second data drive chip labeled with 140(2), the (N-M)th data drive chip is labeled with 140(N-M) and so on, and the Nth data drive chip is labeled with 140(N). In this embodiment, for convenience, the amount of the data drive chip 140 is 6, which are respectively named to be the first data drive chip 140(1), the second data drive chip 140(2), the third data drive chip 140(3), the fourth data drive chip 140(4), the fifth data drive chip 140(5) and the sixth data drive chip 140(6), and are correspondingly marked in figures.

The original Gamma voltage signal is transmitted to the first data drive chip 140(1) to the (N-M)th data drive chip 140(N-M) through the first signal transmission board 110, and the original Gamma voltage signal is transmitted to the second signal transmission board 120 through the first signal transmission board 110 and wires 210 located in a non display region of an array substrate located in the liquid crystal panel 20, and the original Gamma voltage signal is transmitted to the (N-M+1)th data drive chip 140(N-M+1) to the Nth data drive chip 140(N) through the second signal transmission board 120.

The liquid crystal panel drive circuit 10 further comprises N flexible films 150 which are separately located. The N flexible films 150 are correspondingly located to the data drive chips 140 one by one, and the N flexible films 150 are employed to carry the data drive chips 140 correspondingly located to the flexible films 150, and the first flexible film 150(1) to the (N-M)th flexible film 150(N-M) are respectively employed to electrically couple the first signal transmission board and the first data drive chips with the first data drive chip 140(1) to the (N-M)th data drive chip 140(N-M); the (N-M+1)th flexible film 150(N-M+1) to the Nth flexible film 150(N) are respectively employed to electrically couple the second signal transmission board 120 with the (N-M+1)th data drive chip 140(N-M+1) to the Nth data drive chip 140(N). The flexible film 150 at the first signal transmission board 110 which is farthest away from the second signal transmission board 120 to the flexible film 150 at the second signal transmission board 120 which is farthest away from the first signal transmission board 110 are sequentially named to be the first flexible film 150(1) to the Nth flexible film 150(N).

For convenience, the first flexible film is labeled with 150(1), the second flexible film is labeled with 150(2), the (N-M)th flexible film is labeled with 150(N-M), and so on, and the Nth flexible film is labeled with 150(N). In this embodiment, the amount of the data drive chips 140 is 6. Therefore, the amount of the flexible films 150 is 6 as the same. For convenience, these are respectively named to be the first flexible film 150(1), the second flexible film 150(2), the third flexible film 150(3), the fourth flexible film 150(4), the fifth flexible film 150(5) and the sixth flexible film 150(6), and are correspondingly marked in figures.

The liquid crystal panel drive circuit 10 of the present invention further comprises a plurality of gate drive chips (Gate Driver) 170. The gate drive chip 170 is employed to generate a gate signal. The gate signal is used to be outputted to the gate line of the liquid crystal display panel 20 to control on or off of the thin film transistor of the liquid crystal display panel 20. The plurality of gate drive chips 170 are located near one side of the liquid crystal display panel 20. Preferably, the side of the liquid crystal display panel 20 that the gate drive chips 170 are located nearby and the side of the liquid crystal display panel 20 that the first signal transmission board 110 and the second signal transmission board 120 are located nearby intersect.

The liquid crystal panel drive circuit of the present invention further comprises a system control chip 180a and a sequence control chip 180b. The system control chip 180a and the sequence control chip 180b are integrated on the same PCB. The system control chip 180a is employed for the generation of the video signals in the liquid crystal display device applied with the liquid crystal display panel 20, and the sequence control chip 180b is employed for the video signal conversion and the generation of the synchronizing signal. In one embodiment, the system control chip 180a and the sequence control chip 180b can be integrated to be one chip.

In comparison with prior art, in the liquid crystal panel drive circuit 10 of the present invention, the Gamma voltage generation circuit 130 is located on the first signal transmission board 110 to eliminate the required board of locating the Gamma voltage generation module 130, and to reduce the flexible circuit board previously located from the Gamma voltage generation module 130 to the first signal transmission board 110 and the second transmission board 120. Therefore, the material cost of the liquid crystal panel drive circuit 10 of the present invention is lower.

Furthermore, the original Gamma voltage signal is transmitted to the second signal transmission board 120 through the first signal transmission board 110 and wires 210 located in a non display region of an array substrate of the liquid crystal panel 20, and thus, the flexible circuit board is not required as the original Gamma voltage signal is transmitted from the first signal transmission board 110 to the second transmission board 120. Accordingly, the material cost of the liquid crystal panel drive circuit 10 of the present invention can be decreased in advance.

In this embodiment, the first signal transmission board 110 and the second signal transmission board 120 are not coplanar with the array substrate of the liquid crystal panel 20.

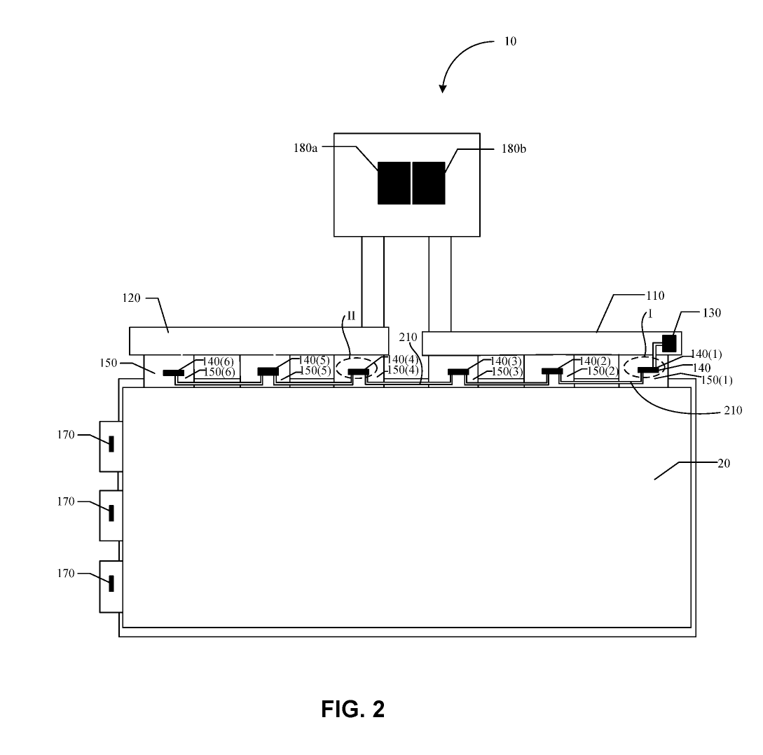

Please refer to FIG. 2. FIG. 2 is a structure diagram of a liquid crystal panel drive circuit according to the second preferred embodiment of the present invention. The difference of this embodiment from the first embodiment is that in this embodiment, the original Gamma voltage signal is transmitted to the first data drive chip 140(1) through the first signal transmission board 110, and the original Gamma voltage signal is transmitted to the second data drive chip 140(2) and the Nth data drive chip 140(N) through wires 210 located in a non display region of an array substrate of the liquid crystal panel 20. The liquid crystal panel drive circuit 10 further comprises N flexible films 150 which are separately located. The N flexible films 150 are correspondingly located to the N data drive chips 140 one by one, and the flexible films 150 are employed to carry the data drive chips 140 correspondingly located to the flexible films 150, and the flexible film 150 carrying the first data drive chip 140(1) is also employed to electrically couple the first signal transmission board 110 with the first data drive chip 140(1) to transmit the original Gamma voltage signal to the first data drive chip 140(1) through the first signal transmission board 110.

Comparing this embodiment with the first preferred embodiment, the original Gamma voltage signal of the liquid crystal panel drive circuit 10 of the present invention is transmitted to the first data drive chip 140(1) through the first signal transmission board 110, and the original Gamma voltage signal is transmitted to the second data drive chip 140(2) and the Nth data drive chip 140(N) through wires 210 located in a non display region of an array substrate of the liquid crystal panel 20. The original Gamma voltage signal transmitted to the second data drive chip 140(2) and the Nth data drive chip 140(N) can pass the first signal transmission board 110 and the second transmission board 120, and thus, the dimensions of the first signal transmission board 110 and the second transmission board 120 can be smaller to decrease the material cost of the liquid crystal panel drive circuit 10 in advance.

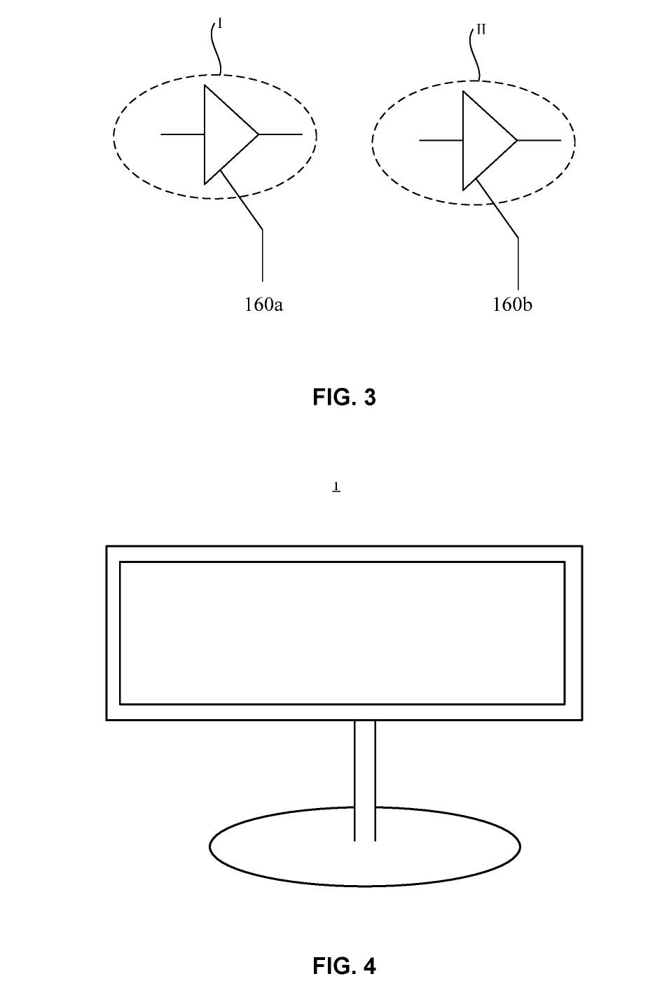

Please refer to FIG. 3. FIG. 3 is an enlarged structure diagram of I position and II position in FIG. 2. In this embodiment, the first data drive chip 140(1) comprises a first amplifier 160a, and the first amplifier 160a is employed to compensate and enhance the original Gamma voltage signal received by the first data drive chip 140(1) in a transmission process. In this embodiment, the (N-M+1)th data drive chip 140(N-M+1) comprises a second amplifier 160b, and the second amplifier 160b is employed to compensate and enhance the original Gamma voltage signal received by the (N-M+1)th data drive chip 140(N-M+1) in a transmission process. In this embodiment, the (N-M+1)th data drive chip 140(N-M+1) is the fourth data drive chip 140(4).

It can be understood that in another embodiment, the first data drive chip 140(1) comprises a first amplifier 160a, and the first amplifier 160a is employed to compensate and enhance the original Gamma voltage signal received by the first data drive chip 140(1) in a transmission process.

It can be understood that in another embodiment, the (N-M+1)th data drive chip 140(N-M+1) comprises a second amplifier 160b, and the second amplifier 160b is employed to compensate and enhance the original Gamma voltage signal received by the (N-M+1)th data drive chip 140(N-M+1) in a transmission process.

Please refer to FIG. 4. FIG. 4 is a structure diagram of a liquid crystal display device according to one preferred embodiment of the present invention. The liquid crystal display device 1 comprises a liquid crystal panel drive circuit 10 and a liquid crystal panel 20. The liquid crystal panel drive circuit 10 can be the liquid crystal panel drive circuit 10 in any of the aforesaid embodiments, and the repeated description is omitted here.

Above are embodiments of the present invention, which does not limit the scope of the present invention. Any modifications, equivalent replacements or improvements within the spirit and principles of the embodiment described above should be covered by the protected scope of the invention.

What is claimed is:

1. A liquid crystal panel drive circuit, employed for driving a liquid crystal panel, wherein the liquid crystal panel drive circuit comprises a first signal transmission board, a second signal transmission board, a Gamma voltage generation module and N data drive chips, and the first signal transmission board and the second signal transmission board are located at the same side of the liquid crystal panel and are separately located with the liquid crystal panel respectively, and the Gamma voltage generation module is located on the first signal transmission board, and the Gamma voltage generation module is employed to generate an original Gamma voltage signal, and the first data drive chip to the (N-M)th data drive chip are separately located between the first signal transmission board and the liquid crystal panel, and the (N-M+1)th data drive chip to the Nth data drive chip are separately located between the second signal transmission board and the liquid crystal panel, and the first data drive chip to the Nth data drive chip are respectively employed to obtain a K scale Gamma voltage drive signal according to the original Gamma voltage signal, and the K scale Gamma voltage drive signal is employed to drive the liquid crystal panel to achieve displays with various brightnesses, wherein N, M and K are all positive integers, and M is smaller than N, and the data drive chip at the first signal transmission board which is farthest away from the second signal transmission board to the data drive chip at the second signal transmission board which is farthest away from the first signal transmission board are sequentially named to be the first data drive chip to the Nth data drive chip.

2. The liquid crystal panel drive circuit according to claim 1, wherein the original Gamma voltage signal is transmitted to the first data drive chip to the (N-M)th data drive chip through the first signal transmission board, and the original Gamma voltage signal is transmitted to the second signal transmission board through the first signal transmission board and wires located in a non display region of an array substrate of the liquid crystal panel, and the original Gamma voltage signal is transmitted to the (N-M+1)th data drive chip to the Nth data drive chip through the second signal transmission board.

3. The liquid crystal panel drive circuit according to claim 2, wherein the liquid crystal panel drive circuit further comprises N flexible films which are separately located, and the N flexible films are correspondingly located to the data drive chips one by one, and the N flexible films are employed to carry the data drive chips correspondingly located to the flexible films, and the first flexible film to the (N-M)th flexible film are respectively employed to electrically couple the first signal transmission board with the first data drive chip to the (N-M)th data drive chip; the (N-M+1)th flexible film to the Nth flexible film are respectively employed to electrically couple the second signal transmission board with the (N-M+1)th data drive chip to the Nth data drive chip, wherein the flexible film at the first signal transmission board which is farthest away from the second signal transmission board to the flexible film at the second signal transmission board which is farthest away from the first signal transmission board are sequentially named to be the first flexible film to the Nth flexible film.

4. The liquid crystal panel drive circuit according to claim 2, wherein the first signal transmission board and the second signal transmission board are not coplanar with the array substrate of the liquid crystal panel.

5. The liquid crystal panel drive circuit according to claim 1, wherein the original Gamma voltage signal is transmitted to the first data drive chip through the first signal transmission board, and the original Gamma voltage signal is transmitted to the second data drive chip and the Nth data drive chip through wires located in a non display region of an array substrate of the liquid crystal panel.

6. The liquid crystal panel drive circuit according to claim 5, wherein the liquid crystal panel drive circuit further comprises N flexible films which are separately located, and the N flexible films are correspondingly located to the N data drive chips one by one, and the flexible films are employed to carry the data drive chips correspondingly located to the flexible films, and the flexible film carrying the first data drive chip is also employed to electrically couple the first signal transmission board with the first data drive chip to transmit the original Gamma voltage signal to the first data drive chip through the first signal transmission board.

7. The liquid crystal panel drive circuit according to claim 6, wherein the first data drive chip comprises a first amplifier, and the first amplifier is employed to compensate and enhance the original Gamma voltage signal received by the first data drive chip in a transmission process.

8. The liquid crystal panel drive circuit according to claim 7, wherein the (N-M+1)th data drive chip comprises a second amplifier, and the second amplifier is employed to compensate and enhance the original Gamma voltage signal received by the (N-M+1)th data drive chip in a transmission process.

9. The liquid crystal panel drive circuit according to claim 6, wherein the (N-M+1)th data drive chip comprises a second amplifier, and the second amplifier is employed to compensate and enhance the original Gamma voltage signal received by the (N-M+1)th data drive chip in a transmission process.

10. A liquid crystal display device, wherein the liquid crystal display device comprises a liquid crystal panel drive circuit, and the liquid crystal panel drive circuit is employed for driving a liquid crystal panel, and the liquid crystal panel drive circuit comprises a first signal transmission board, a second signal transmission board, a Gamma voltage generation module and N data drive chip, and the first signal transmission board and the second signal transmission board are located at the same side of the liquid crystal panel and are separately located with the liquid crystal panel respectively, and the Gamma voltage generation module is located on the first signal transmission board, and the Gamma voltage generation module is employed to generate an original Gamma voltage signal, and the first data drive chip to the (N-M)th data drive chip are separately located between the first signal transmission board and the liquid crystal panel, and the (N-M+1)th data drive chip to the Nth data drive chip are separately located between the second signal transmission board and the liquid crystal panel, and the first data drive chip to the Nth data drive chip are respectively employed to obtain a K scale Gamma voltage drive signal according to the original Gamma voltage signal, and the K scale Gamma voltage drive signal is employed to drive the liquid crystal panel to achieve displays with various brightnesses, wherein N, M and K are all positive integers, and M is smaller than N, and the data drive chip at the first signal transmission board which is farthest away from the second signal transmission board to the data drive chip at the second signal transmission board which is farthest away from the first signal transmission board are sequentially named to be the first data drive chip to the Nth data drive chip.

11. The liquid crystal display device according to claim 10, wherein the original Gamma voltage signal is transmitted to the first data drive chip to the (N-M)th data drive chip through the first signal transmission board, and the original Gamma voltage signal is transmitted to the second signal transmission board through the first signal transmission board and wires located in a non display region of an array substrate of the liquid crystal panel, and the original Gamma voltage signal is transmitted to the (N-M+1)th data drive chip to the Nth data drive chip through the second signal transmission board.

12. The liquid crystal display device according to claim 11, wherein the liquid crystal panel drive circuit further comprises N flexible films which are separately located, and the N flexible films are correspondingly located to the data drive chips one by one, and the N flexible films are employed to carry the data drive chips correspondingly located to the flexible films, and the first flexible film to the (N-M)th flexible film are respectively employed to electrically couple the first signal transmission board with the first data drive chip to the (N-M)th data drive chip; the (N-M+1)th flexible film to the Nth flexible film are respectively employed to electrically couple the second signal transmission board with the (N-M+1)th data drive chip to the Nth data drive chip, wherein the flexible film at the first signal transmission board which is farthest away from the second signal transmission board to the flexible film at the second signal transmission board which is farthest away from the first signal transmission board are sequentially named to be the first flexible film to the Nth flexible film.

13. The liquid crystal display device according to claim 11, wherein the first signal transmission board and the second signal transmission board are not coplanar with the array substrate of the liquid crystal panel.

14. The liquid crystal display device according to claim 10, wherein the original Gamma voltage signal is transmitted to the first data drive chip through the first signal transmission board, and the original Gamma voltage signal is transmitted to the second data drive chip and the Nth data drive chip through wires located in a non display region of an array substrate of the liquid crystal panel.

15. The liquid crystal display device according to claim 14, wherein the liquid crystal panel drive circuit further comprises N flexible films which are separately located, and the N flexible films are correspondingly located to the N data drive chips one by one, and the flexible films are employed to carry the data drive chips correspondingly located to the flexible films, and the flexible film carrying the first data drive chip is also employed to electrically couple the first signal transmission board with the first data drive chip to transmit the original Gamma voltage signal to the first data drive chip through the first signal transmission board.

16. The liquid crystal display device according to claim 15, wherein the first data drive chip comprises a first amplifier, and the first amplifier is employed to compensate and enhance the original Gamma voltage signal received by the first data drive chip in a transmission process.

17. The liquid crystal display device according to claim 16, wherein the (N-M+1)th data drive chip comprises a second amplifier, and the second amplifier is employed to compensate and enhance the original Gamma voltage signal received by the (N-M+1)th data drive chip in a transmission process.

18. The liquid crystal display device according to claim 15, wherein the (N-M+1)th data drive chip comprises a second amplifier, and the second amplifier is employed to compensate and enhance the original Gamma voltage signal received by the (N-M+1)th data drive chip in a transmission process.
